(19) United States
(12) Patent Application Publication
(10) Pub. No.: US 2026/0082828 A1
(43) Pub. Date: Mar. 19, 2026

(54) GUNN DIODE WITH LAYERED STRUCTURE

(71) Applicants: Abhishek A. Sharma, Portland, OR (US); Tahir Ghani, Portland, OR (US); Wilfred Gomes, Portland, OR (US)

(72) Inventors: Abhishek A. Sharma, Portland, OR (US); Tahir Ghani, Portland, OR (US); Wilfred Gomes, Portland, OR (US)

(21) Appl. No.: 18/887,229

(22) Filed: Sep. 17, 2024

(51) Int. Cl. H10N 80/10

(52) U.S. Cl. CPC H10N 80/107

(57) ABSTRACT

Gunn diodes are formed using a set of layered semiconductor materials, with one or more n-doped upper layers and contacts over the uppermost semiconductor layer. A diode may include alternating layers of indium, gallium, and arsenic (e.g., InGaAs) and indium, aluminum, and arsenic (e.g., InAlAs), where an uppermost layer of the stack includes two regions of highly-doped InGaAs, and a layer of InAlAs is directly below the two regions of highly-doped InGaAs. The InAlAs layer forms the active region and is n-doped to a lower dopant concentration than the two InGaAs regions. Further alternating layers of InGaAs and InAlAs may be below the active region. A gate may be included between the two contacts and over the active region; the gate may apply a bias voltage to the active region. The Gunn diodes may advantageously be used in low-temperature environments, such as cooled IC devices.

### BACKGROUND

A Gunn diode, also referred to as a transferred electron device (TED), is a two-terminal device that is characterized by a current-voltage (I-V) curve with a region of negative differential resistance, or more generally, negative impedance. The Gunn diode is based on the Gunn effect, which produces oscillations along the negative differential resistance region. As the electric field applied to the diode increases, the current though the diode initially increases and then decreases in a cyclical manner, leading to periodic fluctuations in current. The current fluctuations produce high-frequency oscillations, typically in the microwave frequencies, e.g., between 300 megahertz (MHz) and 300 gigahertz (GHz).

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIG. 1 illustrates a cross-section of a Gunn diode, according to some embodiments of the present disclosure.

FIG. 2 illustrates example I-V curves for Gunn diodes disclosed herein, according to some embodiments of the present disclosure.

FIG. 3 is a cross-section illustrating a layered Gunn diode structure, according to some embodiments of the present disclosure.

FIG. 4 is a cross-section illustrating a layered Gunn diode structure with asymmetrical contacts, according to some embodiments of the present disclosure.

FIG. 5 is a cross-section illustrating a first gated Gunn diode structure, according to some embodiments of the present disclosure.

FIG. 6 is a cross-section illustrating a second gated Gunn diode structure, according to some embodiments of the present disclosure.

FIG. 7 illustrates an example oscillation response of the Gunn diodes disclosed herein, according to some embodiments of the present disclosure.

FIGS. 8A and 8B are top views of a wafer and dies that include one or more Gunn diodes in accordance with any of the embodiments disclosed herein.

FIG. 9 is a cross-sectional side view of an IC device that may include one or more Gunn diodes in accordance with any of the embodiments disclosed herein.

FIG. 10 is a cross-sectional side view of an IC device assembly that may include one or more Gunn diodes in accordance with any of the embodiments disclosed herein.

FIG. 11 is a block diagram of an example computing device that may include one or Gunn diodes in accordance with any of the embodiments disclosed herein.

FIG. 12 is a block diagram of an example processing device that includes one or more Gunn diodes in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

A diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. Many semiconductor diodes include a p-n junction, which is an interface between two types of semiconductor materials, p-type and n-type. Semiconductor diodes may include silicon, germanium, or other types of semiconductor materials.

Gunn diodes do not include a p-n junction. Instead, Gunn diodes include a stack of n-doped material, with two highly doped regions (referred to as doped regions or n+ regions) near the terminals, and a lightly doped region (referred to as an n region, active region, or buffer region) between the highly doped region. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. The oscillation effect of a Gunn diode is exhibited in stacks of n-type materials with electron charge carriers.

When a voltage is applied across the lightly n-doped active region, an electric field develops across the active region. Initially, current across the device increases, but after reaching the threshold voltage, the Gunn diode operates in a negative differential resistance region in which the current decreases. After a current pulse exits the device, another pulse is generated by again increasing the voltage. The series of current pulses produces a sustained oscillation at an oscillation frequency, where the frequency may be based on device characteristics, such as thickness of the active region and operating temperature.

In a Gunn diode, one of the n+ regions is generally larger than the other, with the current traveling through the larger n+ region, through the n region, and then though the smaller n+ region. The larger n+ region provides good ohmic contact and low contact resistance with the anode, which ensures efficient carrier injection and provides proper electric field distribution through the device.

Gunn diodes have been used as oscillators for various applications, such as radio frequency (RF) communications, microwave transmitters, military radar, and various sensors. For RF devices, the active region and n+ regions each have a thickness of around a micron. As disclosed herein, semiconductor processing techniques can be used to produce Gunn diodes at much smaller scales and that operate at lower voltages. The Gunn diodes disclosed herein be used in integrated circuit (IC) products, for example, to provide an on-die processor clock, or to provide one or more on-die synchronization clocks to enable frequency matching for multi-die systems.

In some embodiments disclosed herein, Gunn diodes are formed using a set of layered semiconductor materials, which may be deposited over a substrate. One or more upper layers may be n-doped, and contacts may be formed over the uppermost semiconductor layer. The layered semiconductor materials may include alternating layers of indium, gallium, and arsenic (e.g., indium gallium arsenide, or InGaAs) and indium, aluminum, and arsenic (e.g., indium aluminum arsenide, or InAlAs). In particular, an uppermost layer of the stack may include two regions of highly-doped InGaAs, where each region forms one of the n+ regions of a Gunn diode. A layer of InAlAs is directly below the two regions of highly-doped InGaAs; this layer forms the active region of the Gunn diode. The InAlAs layer is n-doped at a lower dopant concentration than the two InGaAs regions. The two InGaAs regions may have different sizes and/or dopant concentrations, e.g., with a larger region having a lower dopant concentration at the anode side, and a smaller region having a higher dopant concentration at the cathode side.

Further alternating layers of InGaAs and InAlAs may be below the active layer; these layers may form templating layers for depositing the active layers and highly-doped regions with low rates of defects in the lattice structures. InGaAs and AlGaAs are both III-V semiconductor materials with similar lattice structures. In general, III-V semiconductors materials have high carrier mobilities and high bandgaps. The layers of III-V materials may be deposited over a substrate, which may also be a III-V material, such as InGaAs, InAlAs, gallium arsenide (GaAs), indium arsenide (InAs), or indium phosphide (InP).

In some embodiments, a gate is included between the two contacts and over the active layer. The gate electrode and/or a layer of gate dielectric may be between the two highly-doped InGaAs regions. The gate may apply a bias voltage to the active region of the Gunn diode. For example, the gate may bias the Gunn diode in the negative differential resistance region of its I-V curve.

The Gunn diodes described herein may advantageously be used in low-temperature environments, such as cooled IC devices. In general, when semiconductor devices operate at lower temperatures, they have improved performance. For example, lower temperatures can lead to increased drive currents across transistors, and transistors operating at lower temperatures generally experience lower leakage. In Gunn diodes, a lower temperature leads to a steeper and longer negative differential range, which can improve performance and stability of the Gunn diodes described herein.

The Gunn diodes described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

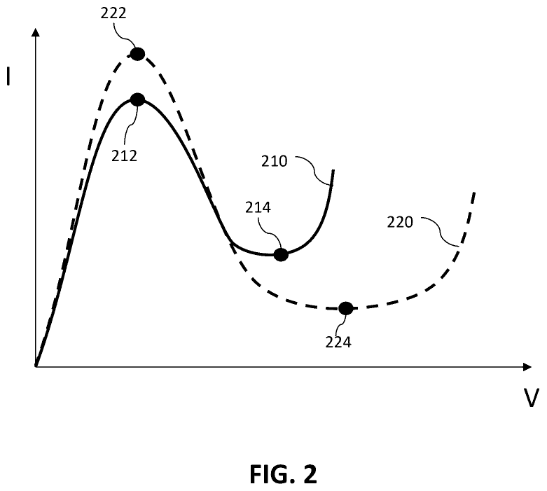

For convenience, if a collection of drawings designated with different letters are present, e.g., FIGS. 2A-2B, such a collection may be referred to herein without the letters, e.g., as “FIG. 2.”

### Example Gunn Diode

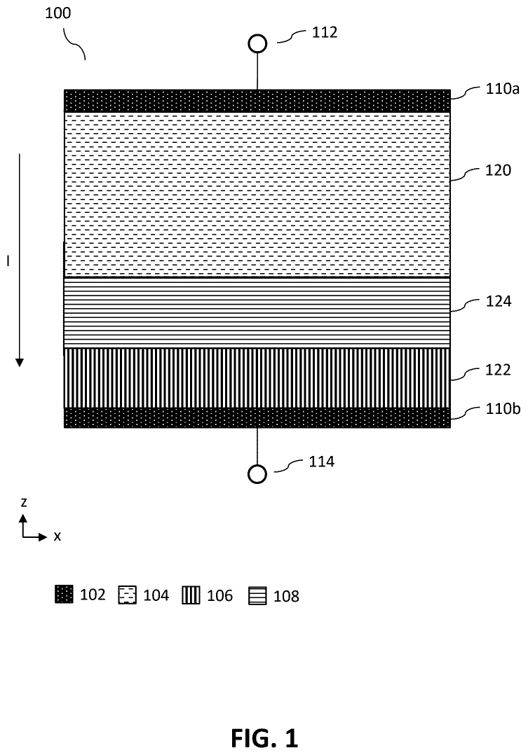

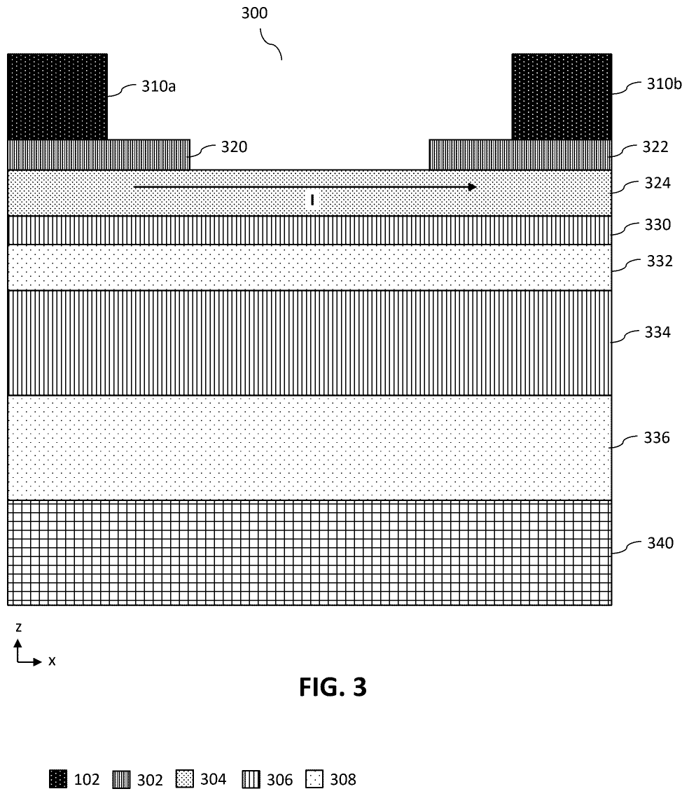

FIG. 1 illustrates a cross-section of a Gunn diode 100, also referred to as a diode 100, according to some embodiments of the present disclosure. The Gunn diode 100 illustrates different regions and materials that may be included in Gunn diode devices. FIGS. 3-6, described further below, illustrate specific layered Gunn diode structures that may include the regions described with respect to FIG. 1.

A number of elements referred to in the description of FIGS. 1 and 3-6 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, a first n+ material 104, a second n+ material 106, and an active material 108.

The diode 100 includes two layers 110a and 110b of the conductor 102, a first n+ region 120 of the first n+ material 104, a second n+ region 122 of the second n+ material 106, and an active region 124 of the active material 108. The layers 110a and 110b are generally referred to as metal layers, and the layers 120-124 are generally referred to as semiconductor layers. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

One or more of the materials 104, 106, and 108 may include a III-V semiconductor, such as combinations of indium, gallium, aluminum, and/or arsenic. In some embodiments, one or more of the semiconductor materials may include a compound semiconductor with a first sub-lattice of at least one element from group III of the periodic table (e.g., Al, Ga, In), and a second sub-lattice of at least one element of group V of the periodic table (e.g., P, As, Sb). For some embodiments, one or more of the semiconductor materials may include a III-V material having a high electron mobility, such as, but not limited to InGaAs, InP, InSb, and InAs. For some such embodiments, one or more of the semiconductor materials may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

The materials 104, 106, and 108 of the first n+ region 120, second n+ region 122, and active region 124, respectively, are selected such that the active region 124 has a lower dopant concentration than the first n+ region 120 and second n+ region 122. The first n+ region 120, second n+ region 122, and active region 124 all have the same charge carrier, i.e., n-type charge carriers. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with electrons as the primary charge carrier is referred to as n-type. Doping may be used to create an n-type material; for example, silicon can be doped with another element such that the resulting doped material is n-type. Suitable n-type dopants for one or more of the materials 104, 106, and 108 may include phosphorus, arsenic, antimony, phosphorous, tellurium, sulfur, tin, silicon, germanium, etc.

In general, the active material 108 may have a relatively low level of a dopant, e.g., a lower dopant concentration than the first n+ material 104 and the second n+ material 106. For example, the first n+ material 104 is a highly-doped n-type material, the active material 108 is a lower-doped n-type material, and the second n+ material 106 is a highly-doped n-type material. The active material 108 may have a dopant concentration on the order of 10¹⁶ to 10¹⁸ cm⁻³. The first n+ material 104 and second n+ material 106 may each have a dopant concentration on the order of 10¹⁸ to 10²⁴ cm⁻³. In some embodiments, the dopant concentration of the n+ materials 104 and 106 is at least ten times greater, at least 100 times greater, or at least 1000 times greater than the dopant concentration of the active material 108. In some embodiments, different dopants (e.g., different ones of the phosphorus, arsenic, antimony, etc.) may be included in different ones of the materials 104, 106, and 108. In some embodiments, the active material 108 may have the same dopant as the first n+ material 104 and/or the second n+ material 106, but at a lower concentration.

In some embodiments, the n+ regions 120 and 122 have different dopant concentrations. The heights selected for the n+ regions 120 and 122 may be inversely related to the dopant concentrations of the n+ regions 120 and 122. At the anode 112, a relatively large collector has a relatively low dopant concentration, and at the cathode 114, a relatively small emitter has a relatively high dopant concentration. For example, the first n+ region 120, which is larger (as shown in FIG. 1), may have a lower dopant concentration than the second n+ region 122, which is smaller.

### Example I-V Curves for Gunn Diode

FIG. 2 illustrates example I-V curves for the Gunn diodes disclosed herein. FIG. 2 illustrates voltage V along the x-axis and current I along the y-axis. FIG. 2 includes two example I-V curves 210 and 220 of a Gunn diode at different operating temperatures. The Gunn diode has a negative differential resistance region, also referred to as an NDR region. In general, in a negative differential resistance device, voltage is a single valued function of the current, but the current is a multivalued function of the voltage. Turning first to the curve 210, the NDR region for this curve 210 is between the points 212 and 214; in this portion of the curve 210, the current decreases as the voltage increases. The voltage at the point 212 is a threshold voltage Vₜₕ for the Gunn diode. When the voltage difference across the Gunn diode increases beyond Vₜₕ, the current density starts to decrease. The current further decreases with an increase in the applied voltage. In this region, the device exhibits negative resistance.

When the current pulse enters the active layer (e.g., the active region 124), the voltage difference across the active layer decreases. This prevents another current pulse from passing through the device until the previous current pulse passes through the other end (e.g., through the cathode 114). The voltage difference across the device then rises again, and another pulse begins traversing the active layer. The current continues pulsing in this manner, producing an oscillation at a particular oscillating frequency. If the voltage were further increased, beyond the point 214, which is referred to as the valley voltage or valley point, the current starts increasing again and the device again exhibits positive resistance.

The curve 210 represents device operation at a first temperature. The second curve 220 represents device operation of the same device at a second temperature that is lower than the first temperature. For example, the curve 210 may characterize a device at 300 Kelvin, and the curve 220 may characterize the same device at 100 Kelvin. The NDR region for the curve 220 is between the points 222 and 224, where the voltage of the point 222 is the threshold voltage Vₜₕ, and the voltage at the point 224 is the valley voltage.

In this example, the threshold voltages of the curves 210 and 220 are the same or substantially the same; in some embodiments, the threshold voltages of the two curves 210 and 220 may be different. The peak current at the threshold voltage of the curve 220 is higher than the peak current at the threshold voltage of the curve 210. In addition, the valley voltage of the curve 220 is higher than the valley voltage of the curve 210, and the current at the valley point 224 is lower than the current at the valley point 214. Furthermore, the curve 210 decreases more sharply or steeply than the curve 220. A Gunn diode may have improved performance at lower temperatures (e.g., at the lower temperature of the second curve 220) as represented by the exaggerated shape of the curve 220 compared to the curve 210.

### Example Cross-Sections of Layered Gunn Diode Structures

FIG. 3 is a cross-section illustrating a layered Gunn diode structure, according to some embodiments of the present disclosure. The Gunn diode 300 is an example implementation of the Gunn diode 100 described above. In this example, rather than the diode being arranged vertically with current traveling in a vertical direction, current travels horizontally, as indicated by the arrow labelled I.

The Gunn diode 300 includes two contacts 310a and 310b, corresponding to the metal layers 110a and 110b of the Gunn diode 100. The diode 300 includes a first n+ region 320, which corresponds to the first n+ region 120 of the diode 100, and a second n+ region 322, which corresponds to the second n+ region 122 of the diode 100. The n+ regions 320 and 322 are electrically coupled and in physical and electrical contact with contacts 310a and 310b, respectively. In particular, contact 310a is over the n+ region 320, and contact 310b is over the n+ region 322.

An active layer 324 or active region 324, which corresponds to the active region 124 of FIG. 1, is in a layer below the n+ regions 320 and 322. The n+ regions 320 and 322 are directly over and in contact with the active layer 324. The n+ regions 320 and 322 are in a layer over the active layer 324, where the n+ regions 324 are arranged at different positions within this layer. Here, the first n+ region 320 is at a different position along the x-direction from the second n+ region 322, and the two n+ regions 320 and 322 are physically separated from each other. In this example, contact 310a is the anode, and contact 310b is the cathode. The active layer 324 is formed over a set of templating layers 330, 332, 334, and 336, which are formed over a substrate 340.

The two n+ regions 320 and 322 include an n+ material 302. The first n+ material 302 may include indium, gallium, and arsenic, e.g., InGaAs or GaInAs. The first n+ material 302 further includes one or more dopants, e.g., any of the n-type dopants described with respect to FIG. 1. The n+ material 302 may have a dopant concentration on the order of 10¹⁸ to 10²⁴ cm⁻³, as described with respect to FIG. 1. While the n+ regions 320 and 322 are both depicted as including the n+ material 302, in some embodiments, the n+ regions 320 and 322 may include different materials. For example, different dopants (e.g., different ones of the phosphorus, arsenic, antimony, etc.) may be included in different ones of the n+ regions 320 and 322. As another example, the two n+ regions 320 and 322 may have the same dopant or same set of dopants, but at different dopant concentrations. For example, the n+ region 320, which is the n+ region at the anode end of the Gunn diode 300, may have a lower dopant concentration than the n+ region 322, which is the n+ region at the cathode end of the Gunn diode 300.

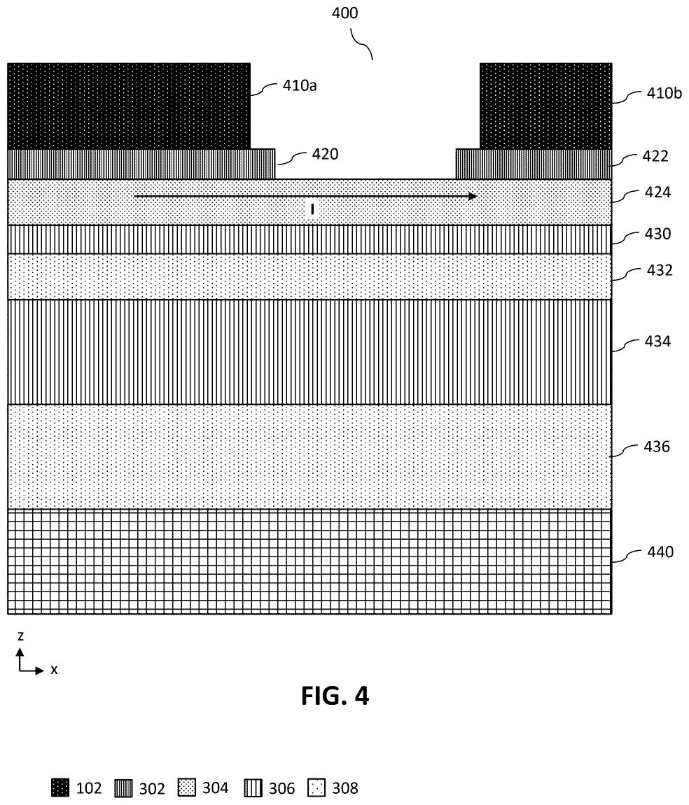

The n+ regions 320 and 322 may have a height or thickness measured in the z-direction in the orientation shown that is less than 20 nm, less than 10 nm, between 1 and 20 nm, between 1 and 10 nm, between 5 and 10 nm, or within some other range. In some embodiments, the n+ regions 320 and 322 have the same or approximately the same thickness (e.g., the thicknesses are within 25%, 10%, or 5% of each other, or within some other tolerance). In some embodiments, one n+ region may be thicker than the other, e.g., the n+ region 320, which is the n+ region at the anode end of the Gunn diode 300, be at least 25% thicker, at least 50% thicker, or at least twice as thick as the n+ region 322, which is the n+ region at the cathode end of the Gunn diode 300. In addition, or alternatively, the n+ regions 320 and 322 may have different widths, as illustrated in FIG. 4.

The active layer 324 includes an active material 304. The active material 304 may include indium, aluminum, and arsenic, e.g., InAlAs. The active material 304 may further include one or more dopants, e.g., any of the n-type dopants described with respect to FIG. 1. The active material 304 may have a relatively low level of a dopant, e.g., a lower dopant concentration than the n+ material 302. The active material 304 may have a dopant concentration on the order of 10¹⁶ to 10¹⁸ cm⁻³. As described with respect to FIG. 1, the dopant concentration of the n+ material 302 may be at least ten times greater than (within one order of magnitude of), at least 100 times greater than (within two orders of magnitude of), or at least 1000 times greater than (within three orders of magnitude of) the dopant concentration of the active material 304. The active layer 324 may have a thickness measured in the z-direction in the orientation shown that is less than 50 nm, less than 30 nm, less than 20 nm, between 10 and 30 nm, between 10 and 20 nm, between 15 and 30 nm, or within some other range.

The n+ regions 320 and 322 and the active layer 324 may be formed using epitaxial growth. In general, epitaxial growth involves crystal growth or material deposition in which crystalline layers are grown over an existing crystal structure, where the grown layers are formed with one or more well-defined orientations with respect to the underlying crystal structure. To form Gunn diodes, the epitaxial growth process is well-controlled and produces crystal layers having a minimal amount of defects. High consistency in crystal structure in the epitaxial growth process may be obtained using the set of templating layers having similar crystal structure to the materials of the Gunn diode 300.

In particular, the upper layers of the structure shown in FIG. 3, e.g., the contacts 310, the layer with the n+ regions 320 and 322, and the active layer 324, may be considered to make up the Gunn diode 300. As noted above, the active layer 324 is formed over a set of templating layers 330, 332, 334, and 336, which are formed over a substrate 340. The templating layers 330-336 may include each include indium, arsenic, and one of gallium or aluminum, alternating between whether gallium or aluminum are included in the layer. The templating layers 330-336 may include low levels of dopants or may not be doped. For example, the uppermost templating layer 330 and, in some cases, one or more lower layers, may include some dopants that migrated from the active layer 324.

The templating layers 330-336 may each have a similar crystal structure to the active material 304 in the active layer 324 and the n+ material 302 in the n+ regions 320 and 322. The active material 304 and the n+ material 302 are single crystal materials that are epitaxially deposited. In general, when a first layer of a first crystalline material (e.g., the active layer 324) is epitaxially deposited over a second layer of a second crystalline material (e.g., the templating layer 330), it is beneficial for the first crystalline material to have a similar structure to the second crystalline material. The similarity of structure helps the first crystalline material form the proper crystal structure when deposited over the second crystalline material. The growing of a first crystalline material over a different, second crystalline material is referred to as heteroepitaxial growth. In this example, forming the active layer 324, and then, the n+ regions 320 and 322 over the stack of templating layers 330-336 may result in the active material 304 and n+ material 302 in the Gunn diode 300 having highly regular crystal structures with minimal defects.

In the embodiment shown, the layers 330 and 334 include a first templating material 306 and the layers 332 and 336 include a second templating material 308. The first templating material 306 may include indium, gallium, and arsenic (e.g., InGaAs), and the second templating material 308 may include indium, aluminum, and arsenic (e.g., InAlAs). While the first templating material 306 and n+ material 302 may both include indium, gallium, and arsenic, the n+ material 302 includes a higher concentration of a dopant than the first templating material 306, which may have a relatively low dopant concentration, or may not be doped. Likewise, while the second templating material 308 and the active material 304 may both include indium, aluminum, and arsenic, the active material 304 includes a higher concentration of a dopant than the second templating material 308, which may have a relatively low dopant concentration, or may not be doped.

The layer 330 may have a thickness or height in the z-direction that is less than 20 nm, less than 10 nm, between 1 and 20 nm, between 1 and 10 nm, between 5 and 10 nm, or within some other range. The layer 332 may have a thickness in the z-direction that is less than 50 nm, less than 30 nm, less than 20 nm, between 10 and 30 nm, between 10 and 20 nm, between 15 and 30 nm, or within some other range. The layer 334 may have a thickness in the z-direction that is less than 50 nm, less than 30 nm, less than 20 nm, between 10 and 50 nm, between 10 and 30 nm, between 20 and 50 nm, or within some other range. The layer 334 may have a thickness in the z-direction that is less than 100 nm, less than 50 nm, less than 20 nm, between 10 and 50 nm, between 25 and 75 nm, between 50 and 100 nm, or within some other range. The layers 336 and 334 may each be thicker than the layers 332 and 330.

The layer 336 may be formed over a substrate 340. The substrate 340 may include a III-V material 308 that serves as a suitable template for depositing the first templating material 306 with a single-crystal structure. For example, the III-V material 308 may include one or more elements from group III of the periodic table (also referred to as the boron group), such as aluminum, gallium, and indium, and one or more elements from group V of the periodic table (also referred to as the nitrogen group), such as nitrogen, phosphorus, arsenic, and antimony. For example, the III-V material 308 may be InGaAs, InAlAs, gallium arsenide (GaAs), indium arsenide (InAs), or indium phosphide (InP), among other examples.

FIG. 4 is a cross-section illustrating a layered Gunn diode structure with asymmetrical contacts, according to some embodiments of the present disclosure. The Gunn diode 400 is another example implementation of the Gunn diode 100 described above. The Gunn diode 400 includes contacts 410, n+ regions 420 and 422, and an active layer 424. The Gunn diode 400 is formed over a set of templating layers 430-436, which are similar to the layers 330-336 of FIG. 3. The layers 430-436 are over a substrate 440, which is similar to the substrate 340 of FIG. 3.

The Gunn diode 400 includes two contacts 410a and 410b, corresponding to the metal layers 110a and 110b of the Gunn diode 100. Contacts 410a and 410b are similar to contacts 310a and 310b, except that whereas contacts 310a and 310b were symmetric in the cross-section shown in FIG. 3, with equal widths in the x-direction, contacts 410a and 410b are asymmetric in the cross-section illustrated in FIG. 4, with different widths in the x-direction. In this example, contact 410a is wider than contact 410b. For example, contact 410a may be at least 25% wider, at least 50% wider, or at least twice as side as contact 410b. Contacts 410a and 410b may additionally or alternatively have different widths in the y-direction, e.g., contact 410a may have a greater width in the y-direction (e.g., into the page in the orientation shown) than contact 410b.

The diode 400 further includes a first n+ region 420, which corresponds to the first n+ region 120 of the diode 100, and a second n+ region 422, which corresponds to the second n+ region 122 of the diode 100. The n+ regions 420 and 422 include the n+ material 302, which may be doped InGaAs, as described above. The n+ regions 420 and 422 are similar to the n+ regions 320 and 322, except that whereas n+ regions 320 and 322 were symmetric in the cross-section shown in FIG. 3, with equal widths in the x-direction, n+ regions 420 and 422 are asymmetric in the cross-section illustrated in FIG. 4, with different widths in the x-direction. In this example, n+ region 420 is wider than n+ region 422. For example, n+ region 420 may be at least 25% wider, at least 50% wider, or at least twice as side as n+ region 422. N+ regions 420 and 422 may additionally or alternatively have different widths in the y-direction, e.g., n+ region 420 may have a greater width in the y-direction (e.g., into the page in the orientation shown) than n+ region 422. In some embodiments, n+ region 420 may additionally or alternatively be taller than n+ region 422, e.g., as shown in FIG. 1. As noted above, the dopant concentrations of the n+ regions 420 and 422 may be different, e.g., the larger n+ region 420 may have a lower dopant concentration than the smaller n+ region 422.

In general, the n+ region 420, which corresponds to the anode, may be larger than the n+ region 422. An area of contact between the n+ region 420 and the contact 410a may have a larger area than an area of contact between the n+ region 422 and the contact 410b. Likewise, an area of contact between the n+ region 420 and the active layer 424 may have a larger area than an area of contact between the n+ region 422 and the active layer 424. In some embodiments, the contact area between the n+ region 422 and the active layer 424 is larger than the contact area between the n+ region 420 and the active layer 424, while the contact area between the respective n+ regions 420 and 422 and the contacts 410a and 410b are the same, e.g., if the contacts 410a and 410b have equal sizes.

### Example Cross-Sections of Gated Layered Gunn Diode Structures

The example diodes 300 and 400 are two-terminal devices. In some embodiments, a Gunn diode may include a gate electrically coupled to the active layer. The gate may apply a bias voltage to the Gunn diode, e.g., to bias the Gunn diode into the NDR region described with respect to FIG. 2.

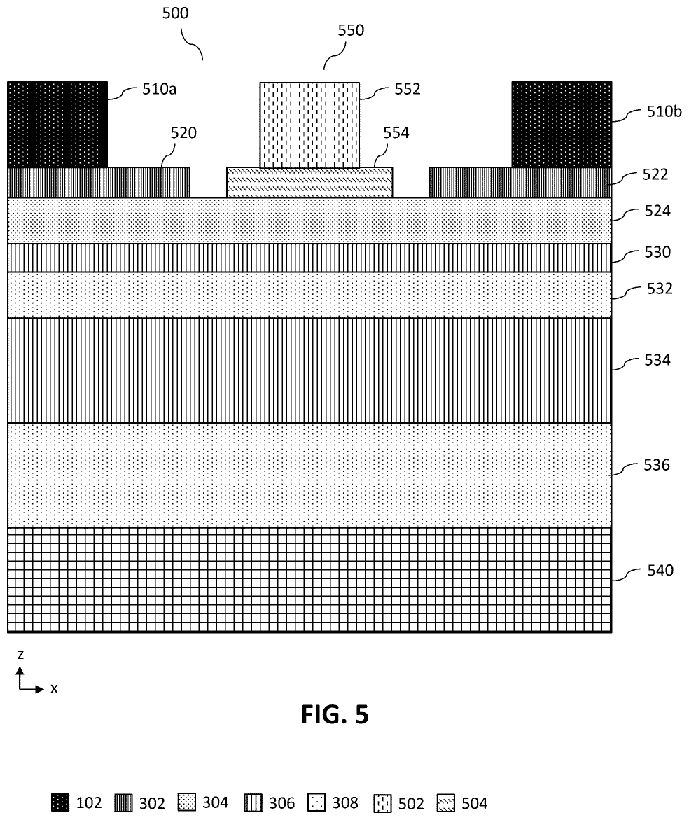

FIG. 5 is a cross-section illustrating a first gated Gunn diode structure, according to some embodiments of the present disclosure. The Gunn diode 500 includes contacts 510a and 510b, n+ regions 520 and 522, and an active layer 524. The contacts 510 are similar to the contacts 310 of FIG. 3. The n+ regions 520 and 522 are similar to the n+ regions 320 and 322 of FIG. 3. The active layer 524 is similar to the active layer 324 of FIG. 3. The Gunn diode 500 is formed over a set of templating layers 530-536, which are similar to the layers 330-336 of FIG. 3. The layers 530-536 are over a substrate 540, which is similar to the substrate 340 of FIG. 3.

The Gunn diode 500 further includes a gate 550 coupled to the active layer 524. Like the n+ regions 320 and 322, the n+ regions 520 and 522 are in a same layer over the active layer 524, and the n+ regions 520 and 522 are at different positions along the x-direction. The gate 550 is between the two contacts 510a and 510b and between the two n+ regions 520 and 522. The gate 550 includes a gate electrode 552, which includes an electrode material 502, and a gate dielectric 554, which includes a dielectric material 504. The electrode material 502 may include at least one metal, and in particular, one or more n-type work function metals, such as hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 552 may include a stack of two or more metal layers, e.g., where one or more metal layers are work function metal layers and at least one metal layer is a fill metal layer.

In various embodiments, the dielectric material 504 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the dielectric material 504 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the dielectric material 504 includes nitrogen, e.g., silicon nitride, silicon oxynitride, aluminum nitride, aluminum oxynitride, zinc nitride, hafnium nitride, etc. In some embodiments, the gate dielectric 504 may have a thickness between about 0.5 nanometers and 10 nanometers, including all values and ranges therein, e.g., between about 1 and 5 nanometers, or between about 1 and 3 nanometers.

In this example, the gate dielectric 554 is within the same layer as the n+ regions 520 and 522, and the gate electrode 552 is within the same layer as the contacts 510a and 510b. In other examples, at least a portion of the gate electrode 552 may be in the same layer as the n+ regions 520 and 522 (e.g., if the gate dielectric 554 is thinner than the n+ regions 520 and 522), or at least a portion of the gate dielectric 554 may be in the same layer as the contacts 510a and 510b (e.g., if the gate dielectric 554 is thicker than the n+ regions 520 and 522).

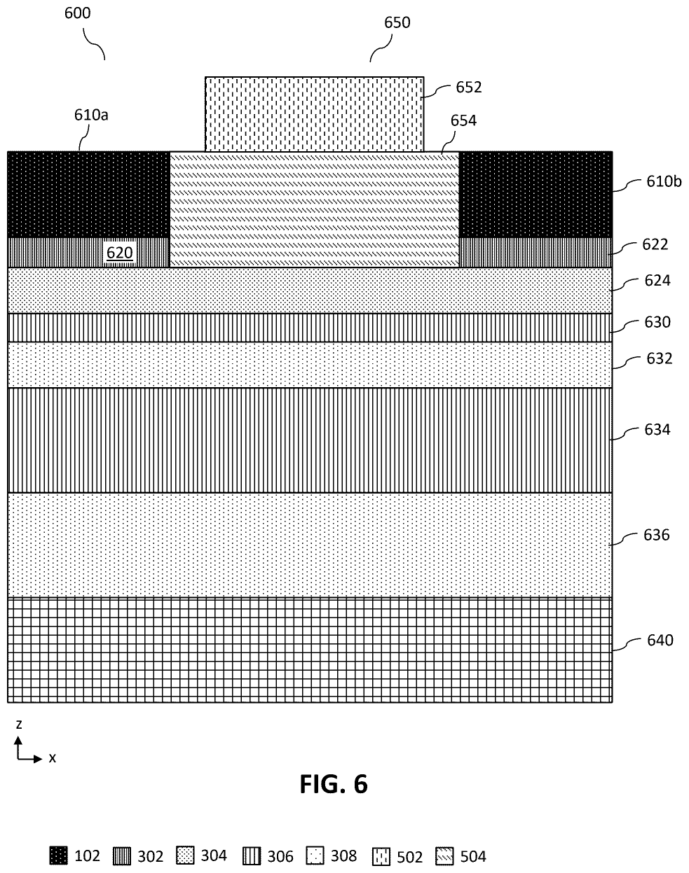

FIG. 6 is a cross-section illustrating a second gated Gunn diode structure, according to some embodiments of the present disclosure. The Gunn diode 600 includes contacts 610a and 610b, n+ regions 620 and 622, and an active layer 624. The contacts 610 are similar to the contacts 310 of FIG. 3. The n+ regions 620 and 622 are similar to the n+ regions 320 and 322 of FIG. 3. The active layer 624 is similar to the active layer 324 of FIG. 3. The Gunn diode 600 is formed over a set of templating layers 630-636, which are similar to the layers 330-336 of FIG. 3. The layers 630-636 are over a substrate 640, which is similar to the substrate 340 of FIG. 3.

The Gunn diode 600 further includes a gate 650 coupled to the active layer 624. The gate 650 includes a gate electrode 652, which includes the electrode material 502 described with respect to FIG. 5, and a gate dielectric 654, which includes the dielectric material 504 described with respect to FIG. 5. The gate 650 is between the two contacts 610a and 610b and between the two n+ regions 620 and 622. In particular, in this example, the gate dielectric 654 extends between the two contacts 610a and 610b and between the two n+ regions 620 and 622. The gate electrode 652 is over the gate dielectric 654, and a bottom surface of the gate electrode 652 is above the top surfaces of the n+ regions 620 and 622. The bottom surface of the gate electrode 652 may be even with (as shown in FIG. 6) or, alternatively, above or below the top surfaces of the contacts 610a and 610b.

### Example Oscillation Response for Gunn Diodes

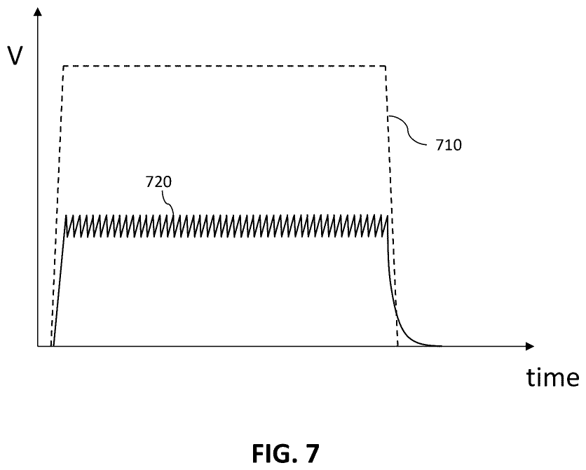

FIG. 7 illustrates an example oscillation response of the Gunn diodes disclosed herein, according to some embodiments of the present disclosure. FIG. 7 illustrates voltage V along the y-axis and time along the x-axis, showing a voltage response over a period of time. FIG. 7 includes an input voltage pulse 710 and an output oscillation voltage 720, where the input voltage pulse 710 is applied to a Gunn diode (e.g., any of the Gunn diodes shown in FIGS. 3-6), and the output oscillation voltage 720 illustrates the response of the Gunn diode to the input voltage pulse 710. To produce the output oscillation voltage 720, the input voltage pulse 710, optionally in combination with a voltage applied at a gate (e.g., the gate illustrated in FIG. 5 or FIG. 6), causes the Gunn diode to enter its NDR region, as described with respect to FIG. 2.

The oscillation frequency of the output oscillation voltage 720 may vary based on the input voltage and/or the operating temperature of the Gunn diode. For example, for a particular device, an operating temperature of 300 Kelvin (K) and an input voltage pulse of 1.8 V may produce an output with an oscillation frequency of around 2 gigahertz (GHz), while a lower operating temperature of 4 K and the same input voltage pulse of 1.8 V may produce an output with a lower oscillation frequency, e.g., between 1 and 1.5 GHz, e.g., around 1.25 GHz. As another example, for a Gunn diode with an operating temperature of 300 K and a lower input voltage pulse of 1.6 V, the output may have an oscillation frequency of less than 1 GHz, e.g., around 0.75 GHz. In this example, keeping the input voltage of 1.6 V and lowering the operating temperature to 4 K may increase the oscillation frequency, e.g., to around 0.9 or 1 GHz.

### Example Devices

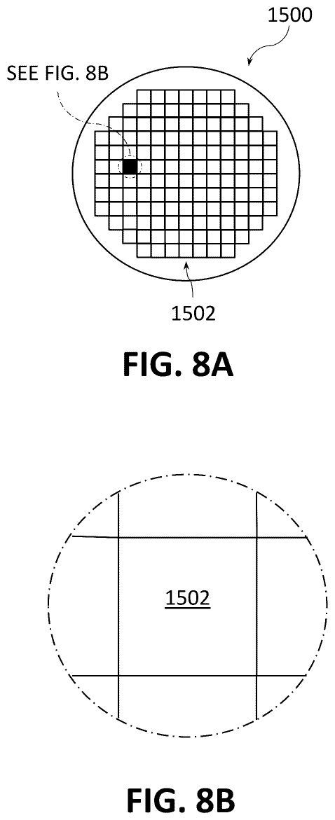

The Gunn diodes, and circuits including Gunn diodes, as disclosed herein may be included in any suitable electronic device. FIGS. 8-12 illustrate various examples of apparatuses that may include the one or more Gunn diodes disclosed herein, which may have been fabricated using the processes disclosed herein.

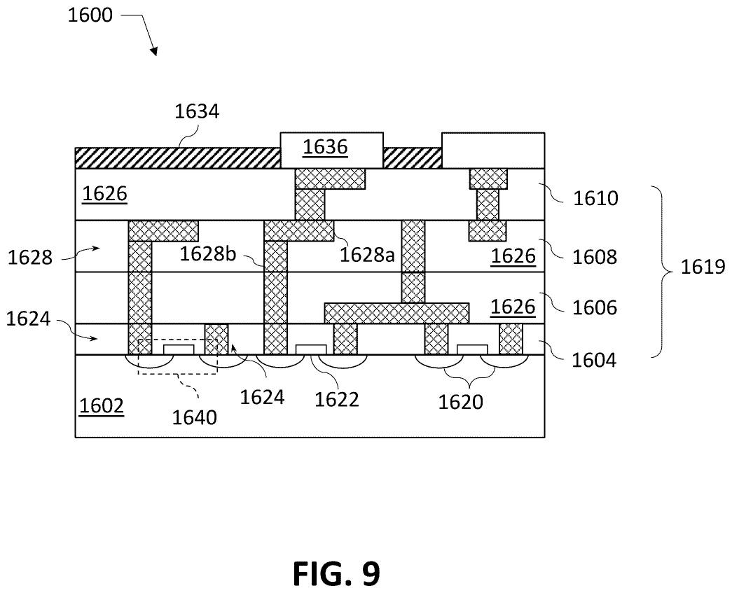

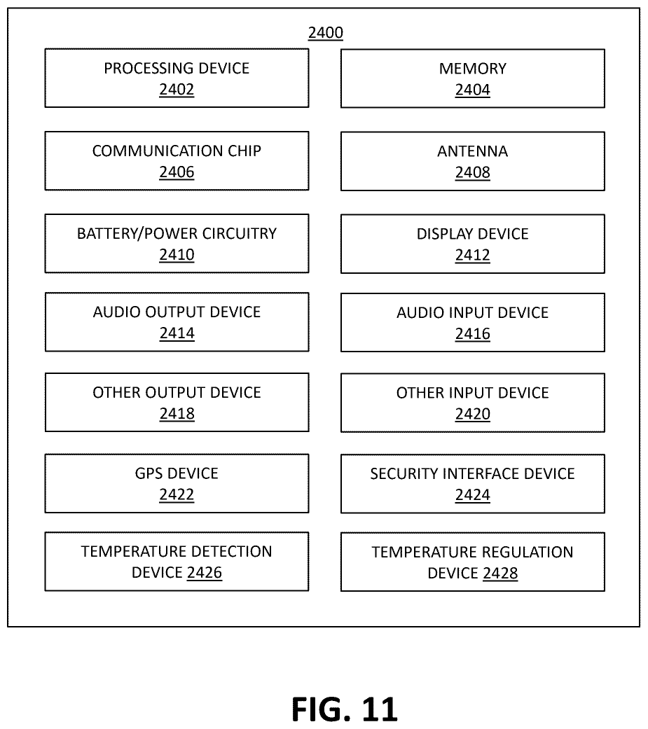

FIGS. 8A and 8B are top views of a wafer and dies that include one or more IC structures including one or more Gunn diodes in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1, 2, and 4-7, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more Gunn diodes in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer.

Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat”upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more Gunn diodes at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

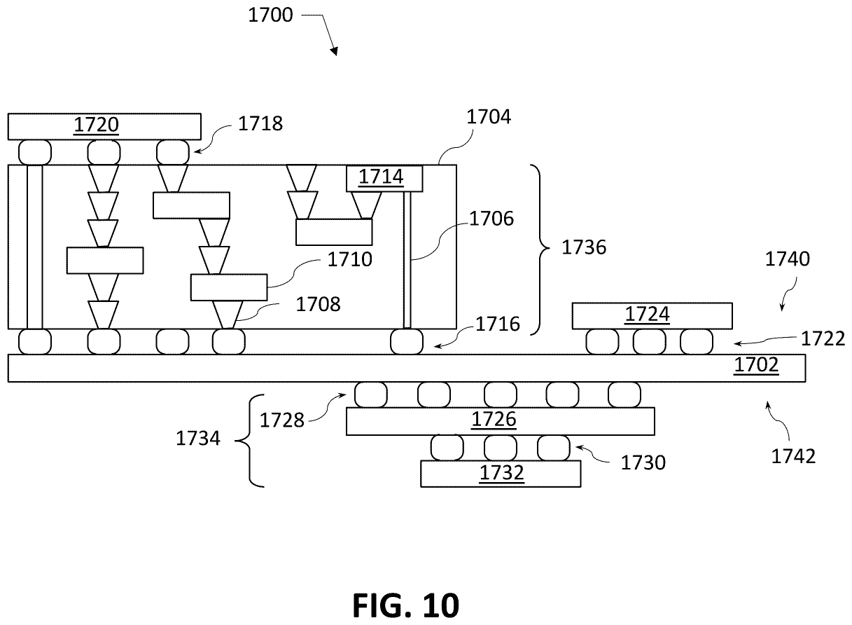

FIG. 10 is a cross-sectional side view of an IC device assembly 1700 that may include components having or being associated with (e.g., being electrically connected by means of) one or more Gunn diodes in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10) male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more Gunn diodes, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 2400 that may include one or more components including one or more Gunn diodes in accordance with any of the embodiments disclosed herein. For example, any suitable ones of the components of the computing device 2400 may include a die (e.g., the die 1502 of FIG. 8) having one or more Gunn diodes as described herein. Any one or more of the components of the computing device 2400 may include, or be included in, an IC device 1600 of FIG. 9 or an IC device assembly 1700 of FIG. 10.

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

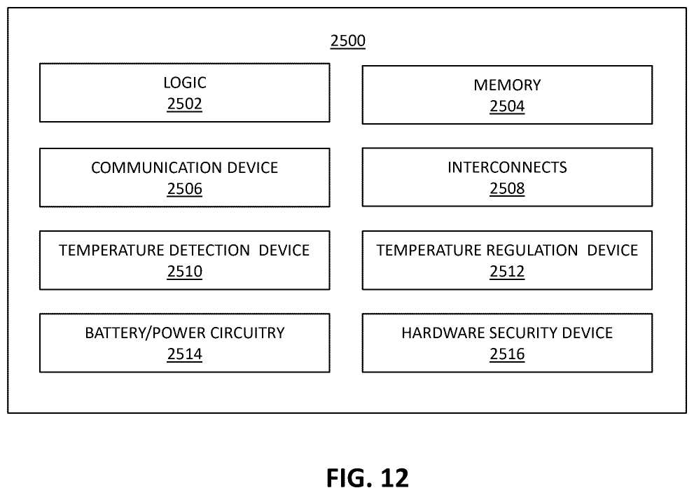

FIG. 12 is a block diagram of an example processing device 2500 that may include one or more IC devices with one or more Gunn diodes in accordance with any of the embodiments disclosed herein. For example, any suitable ones of the components of the processing device 2500 may include a die (e.g., the die 1502 of FIG. 8) having one or more Gunn diodes as described herein. Any one or more of the components of the processing device 2500 may include, or be included in, an IC device assembly 1700 (FIG. 9). Any one or more of the components of the processing device 2500 may include, or be included in, an IC device 1600 of FIG. 9 or an IC device assembly 1700 of FIG. 10. Any one or more of the components of the processing device 2500 may include, or be included in, a computing device 2400 of FIG. 11; for example, the processing device 2500 may be the processing device 2402 of the computing device 2400.

A number of components are illustrated in FIG. 12 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 12, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 11). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 11). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 11 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 11 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 11. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 11. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.

Example 1 provides a device including a first region extending in a first direction, the first region including indium, aluminum, and arsenic; a second region over a first portion of the first region; and a third region over a second portion of the first region, the second region and the third region arranged at different positions along the first direction, the second region and the third region including indium, gallium, and arsenic.

Example 2 provides the device of example 1, where the first region has a first n-type doping concentration, the second region has a second n-type doping concentration, and the second n-type doping concentration is greater than the first n-type doping concentration.

Example 3 provides the device of example 2, where the third region has a third n-type doping concentration, and the third n-type doping concentration is greater than the first n-type doping concentration.

Example 4 provides the device of example 3, where the third n-type doping concentration is within an order of magnitude of the second n-type doping concentration.

Example 5 provides the device of any preceding example, where the second region has a first width along the first direction, the third region has a second width along the first direction, and the first width is greater than the second width.

Example 6 provides the device of example 5, where the third region has a higher n-type doping concentration than the second region.

Example 7 provides the device of any preceding example, further including a fourth region under the first region, the fourth region including indium, gallium, and arsenic.

Example 8 provides the device of example 7, further including a fifth region under the fourth region, the fifth region including indium, aluminum, and arsenic.

Example 9 provides the device of example 8, further including a sixth region under the fifth region, the sixth region including indium, gallium, and arsenic.

Example 10 provides the device of example 9, further including a seventh region under the sixth region, the seventh region including indium, aluminum, and arsenic.

Example 11 provides the device of any preceding example, where the device is formed over a substrate, the substrate including a III-V material.

Example 12 provides the device of any preceding example, further including a gate over a third portion of the first region, the third portion between the first portion and the second portion.

Example 13 provides the device of example 12, where the gate is over a dielectric region, the dielectric region between the gate and the first region, and the dielectric region between the second region and the third region.

Example 14 provides a device including a first layer including indium, aluminum, and arsenic; a second layer including indium, gallium, and arsenic; a third layer including a first doped semiconductor region and a second doped semiconductor region, where the first and second doped semiconductor regions include indium, gallium, and arsenic, and where the first layer is between the second layer and the third layer; a first conductive structure coupled (e.g., conductively coupled, e.g., directly electrically connected and/or directly physically connected) to the first doped semiconductor region; and a second conductive structure coupled (e.g., conductively coupled, e.g., directly electrically connected and/or directly physically connected) to the second doped semiconductor region.

Example 15 provides the device of example 14, the third layer further including a dielectric region, the dielectric region between the first doped semiconductor region and the second doped semiconductor region.

Example 16 provides the device of example 15, further including a third conductive structure, where the dielectric region is between the third conductive structure and the first layer.

Example 17 provides the device of any of examples 14-16, where the first layer has a first n-type doping concentration, the first region of the third layer has a second n-type doping concentration, and the second n-type doping concentration is greater than the first n-type doping concentration.

Example 18 provides the device of any of examples 14-17, further including a fourth layer including indium, aluminum, and arsenic, the second layer between the first layer and the fourth layer; and a fifth layer including indium, gallium, and arsenic, the fourth layer between the second layer and the fifth layer.

Example 19 provides the device of any of examples 14-18, where a distance between the second layer and the third layer is between 10 and 30 nanometers.

Example 20 provides the device of any of examples 14-19, where a distance between the first layer and the first conductive structure is between 5 and 10 nanometers.

Example 21 provides a diode including a first layer including indium, aluminum, and arsenic, the first layer having a first thickness between 10 nanometers (nm) and 30 nm; and a second layer including a first region over a first portion of the first layer; and a second region over a second portion of the first layer, the first region and the second region including indium, gallium, and arsenic, and the second layer having a second thickness between 5 and 10 nm.

Example 22 provides the diode of example 21, where the second thickness is less than the first thickness.

Example 23 provides the diode of example 21 or 22, where the first layer further includes an n-dopant.

Example 24 provides the diode of example 23, where the second layer further includes an n-dopant, and a dopant concentration of the second layer is greater than a dopant concentration of the first layer.

Example 25 provides the diode of any of examples 21-24, where the diode is in an IC device, and the IC device is coupled (e.g., conductively coupled, e.g., directly electrically connected) to a circuit board.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a first region extending in a first direction, the first region comprising indium, aluminum, and arsenic;
a second region over a first portion of the first region; and
a third region over a second portion of the first region, the second region and the third region arranged at different positions along the first direction, the second region and the third region comprising indium, gallium, and arsenic.

2. The device of claim 1, wherein the first region has a first n-type doping concentration, the second region has a second n-type doping concentration, and the second n-type doping concentration is greater than the first n-type doping concentration.

3. The device of claim 2, wherein the third region has a third n-type doping concentration, and the third n-type doping concentration is greater than the first n-type doping concentration.

4. The device of claim 3, wherein the third n-type doping concentration is within an order of magnitude of the second n-type doping concentration.

5. The device of claim 1, wherein the second region has a first width along the first direction, the third region has a second width along the first direction, and the first width is greater than the second width.

6. The device of claim 5, wherein the third region has a higher n-type doping concentration than the second region.

7. The device of claim 1, further comprising a fourth region under the first region, the fourth region comprising indium, gallium, and arsenic.

8. The device of claim 7, further comprising a fifth region under the fourth region, the fifth region comprising indium, aluminum, and arsenic.

9. The device of claim 8, further comprising a sixth region under the fifth region, the sixth region comprising indium, gallium, and arsenic.

10. The device of claim 9, further comprising a seventh region under the sixth region, the seventh region comprising indium, aluminum, and arsenic.

11. The device of claim 1, further comprising a gate over a third portion of the first region, the third portion between the first portion and the second portion.

12. The device of claim 11, wherein the gate is over a dielectric region, the dielectric region between the gate and the first region, and the dielectric region between the second region and the third region.

13. A device comprising:
a first layer comprising indium, aluminum, and arsenic;
a second layer comprising indium, gallium, and arsenic;
a third layer comprising a first doped semiconductor region and a second doped semiconductor region, wherein the first and second doped semiconductor regions comprise indium, gallium, and arsenic, and wherein the first layer is between the second layer and the third layer;
a first conductive structure coupled to the first doped semiconductor region; and
a second conductive structure coupled to the second doped semiconductor region.

14. The device of claim 13, the third layer further comprising a dielectric region, the dielectric region between the first doped semiconductor region and the second doped semiconductor region.

15. The device of claim 14, further comprising a third conductive structure, wherein the dielectric region is between the third conductive structure and the first layer.

16. The device of claim 13, wherein the first layer has a first n-type doping concentration, the first region of the third layer has a second n-type doping concentration, and the second n-type doping concentration is greater than the first n-type doping concentration.

17. The device of claim 13, wherein a distance between the second layer and the third layer is between 10 and 30 nanometers.

18. The device of claim 13, wherein a distance between the first layer and the first conductive structure is between 5 and 10 nanometers.

19. A diode comprising:
a first layer comprising indium, aluminum, and arsenic, the first layer having a first thickness between 10 nanometers (nm) and 30 nm; and
a second layer comprising:
a first region over a first portion of the first layer; and
a second region over a second portion of the first layer, the first region and the second region comprising indium, gallium, and arsenic, and the second layer having a second thickness between 5 and 10 nm.

20. The diode of claim 19, wherein the diode is in an IC device, and the IC device is coupled to a circuit board.
